(19) United States
(12) Patent Application Publication
(10) Pub. No.: US 2025/0037960 A1
(43) Pub. Date: Jan. 30, 2025

(54) BLANKING APERTURE ARRAY SYSTEM, CHARGED PARTICLE BEAM WRITING APPARATUS, AND METHOD FOR INSPECTING BLANKING APERTURE ARRAY SYSTEM

(71) Applicant: NuFlare Technology, Inc., Yokohama-shi (JP)

(72) Inventors: Kei HASEGAWA, Yokohama-shi (JP); Hayato KIMURA, Sunto-gun (JP)

(73) Assignee: NuFlare Technology, Inc., Yokohama-shi (JP)

(21) Appl. No.: 18/914,392

(22) Filed: Oct. 14, 2024

Related U.S. Application Data
(63) Continuation of application No. PCT/JP2023/016573, filed on Apr. 27, 2023.

(30) Foreign Application Priority Data
May 13, 2022 (JP) 2022-079620

(51) Int. Cl. H01J 37/04; H01J 37/302; H01J 37/317

(52) U.S. Cl. CPC H01J 37/045; H01J 37/302; H01J 37/3177; H01J 2237/0435

(57) ABSTRACT

A controller supplies, during beam irradiation, a shift register with control data which causes flip-flops to hold a “1” value and has a first voltage, and supplies, during a period except for the beam irradiation, the shift register with the control data which causes the flip-flops to hold a “1” value and has a second voltage lower than the first voltage to determine whether the flip-flops are operating normally by determining whether the control data supplied to the shift register coincides with control data output from one flip-flop or by determining whether a state to be obtained by blanking by a first electrode coupled to a first flip-flop in accordance with the control data supplied to the shift register coincides with a state by blanking by the first electrode in accordance with the control data supplied to the shift register.

### CROSS-REFERENCE TO RELATED APPLICATION

This application is a Continuation Application of PCT Application No. PCT/JP2023/016573, filed Apr. 27, 2023 and based upon and claiming the benefit of priority from Japanese Patent Application No. 2022-079620, filed May 13, 2022, the entire contents of all of which are incorporated herein by reference.

### FIELD

Embodiments described herein relate generally to a blanking aperture array system, a charged particle beam writing apparatus and a method for inspecting the blanking aperture array system.

### BACKGROUND

Masks are used for manufacturing semiconductor devices. To shrink elements, mask patterns should be shrunk. To form masks with shrunk patterns, the patterns are written on the materials of the masks using electron beams. To form the masks with efficiency, a writing system (multi-beam writing system) using a plurality of electron beams may be used.

In the multi-beam writing system, electron beams are caused to pass through a mask (shaping aperture array plate) having a plurality of apertures to form multi-beam. The multi-beam is directed toward a blanking aperture array mechanism having a plurality of apertures. The beams are deflected individually by the blanking aperture array mechanism, and the deflected beams hit a shield and thus do not reach the masks.

The blanking aperture array mechanism includes a mechanism surrounding each of the apertures to change the beams that pass through the apertures. The mechanism includes electrodes and electronic circuit elements for applying a voltage to the electrodes.

The electron beams emitted for writing may damage the electronic circuit elements in the blanking aperture array mechanism. The damages may be accumulated to degrade the characteristics of the elements. If the degradation of the characteristics exceeds a certain critical point, the electronic circuit elements may fail and, in this case, the blanking aperture array mechanism cannot operate accurately. To avoid this, the blanking aperture array mechanism can be diagnosed prior to writing. If a failure is detected in an element at the time of the diagnosis, it can be dealt with prior to writing. In this failure diagnosis, however, it is only at the time of the diagnosis that the failed element can be identified. For this reason, if an element does not fail at the time of diagnosis though its degradation may be in progress, a failure cannot be detected from the element during the next writing.

On the other hand, writing takes time. During the writing, parts of a writing apparatus cannot be replaced. If, therefore, an element is determined as a normal one by diagnosis but it fails during the writing, the blanking aperture array mechanism needs to be replaced and writing needs to be performed again. This may seriously derail mask production plans.

### BRIEF DESCRIPTION OF THE DRAWINGS

FIG. 1 shows elements of a writing apparatus according to a first embodiment.

FIG. 2 shows a hardware configuration of a controller of the first embodiment.

FIG. 3 shows a structure of a shaping aperture array plate of the first embodiment along the xy plane.

FIG. 4 shows a structure of a blanking aperture array mechanism of the first embodiment along the xz plane.

FIG. 5 shows a structure of the blanking aperture array mechanism of the first embodiment along the xy plane.

FIG. 6 shows a circuit and its related elements of the blanking aperture array mechanism of the first embodiment.

FIG. 7 shows some elements of a shift register of the first embodiment and coupling of the elements, and their related elements.

FIG. 8 shows a shift register of the first embodiment and its related elements.

FIG. 9 shows an example of elements of a D-type flip-flop of the first embodiment and coupling of the elements.

FIG. 10 shows an example of elements of a NAND gate of the first embodiment and coupling of the elements.

FIG. 11 shows an example of elements of an inverter of the first embodiment and coupling of the elements.

FIG. 12 shows functional blocks of the controller of the first embodiment.

FIG. 13 shows a flow of an operation performed by the writing apparatus according to the first embodiment.

FIG. 14 shows characteristics of a transistor TN of the first embodiment.

FIG. 15 shows an example of characteristics and applied voltages of the transistor TN of the first embodiment.

FIG. 16 shows the relationship between degradation and use time of the transistor TN of the first embodiment.

FIG. 17 shows a flow of a writing and inspection method of a modification to the first embodiment.

### DETAILED DESCRIPTION

Based on the current situation described above, it is desirable to provide a blanking aperture array system, a charged particle beam writing apparatus and a method for inspecting the blanking aperture array system, which are capable of identifying an element that may fail in the near future even if the element is not determined as failing by prior diagnosis.

A blanking aperture array system for use in a multi-charged particle beam irradiation apparatus according to one embodiment includes a blanking aperture array substrate and a controller.

The blanking aperture array substrate includes a shift register including a plurality of flip-flops coupled in series and configured to transfer control data for beam irradiation; and first electrodes respectively coupled to the flip-flops and formed on a substrate and second electrodes coupled to ground, one of the first electrodes and one of the second electrodes sandwiching one of a plurality of apertures through which a beam is transmitted. The controller supplies, during beam irradiation, the shift register with the control data which causes the flip-flops to hold a “1” value and has a first voltage that is used during beam irradiation; and supplies, during a period except for the beam irradiation, the shift register with the control data which causes the flip-flops to hold a “1” value and has a second voltage that is lower than the first voltage to determine whether the flip-flops are operating normally by determining whether the control data supplied to the shift register coincides with control data output from one of the flip-flops in the shift register as a result of the control data transferred through the shift register or by determining whether a state to be obtained by blanking by one of the first electrodes coupled to a first flip-flop in the shift register in accordance with the control data supplied to the shift register coincides with a state obtained by blanking by the one of the first electrodes coupled to the first flip-flop in accordance with the control data supplied to the shift register.

Embodiments will now be described with reference to the figures. In the following description, components with substantially the same functionalities and configurations will be referred to with the same reference symbols, and repeated descriptions may be omitted. In order to distinguish components having substantially the same function and configuration from each other, an additional numeral or letter may be added to the end of each reference numeral.

The entire description of a particular embodiment applies to another embodiment unless an explicit mention is made otherwise, or an obvious elimination is involved. Each functional block may be implemented as hardware, computer software, or their combination. It is not necessary that functional blocks be distinguished as in the following examples. For example, some of the functions may be implemented by functional blocks different from those illustrated below. Furthermore, an illustrated functional block may be divided into functional sub-blocks.

In addition, any step in a flow of a method of an embodiment is not limited to any illustrated order, and can occur in an order different from an illustrated order and/or can occur concurrently with another step.

In the specification and the claims, when a particular first component is expressed as being “coupled” to another second component, the first component may be coupled to the second component either directly or via one or more components which are always or selectively conductive.

The embodiments will be described using an xyz orthogonal coordinate system.

### 1. First Embodiment

### 1.1. Structure (Configuration)

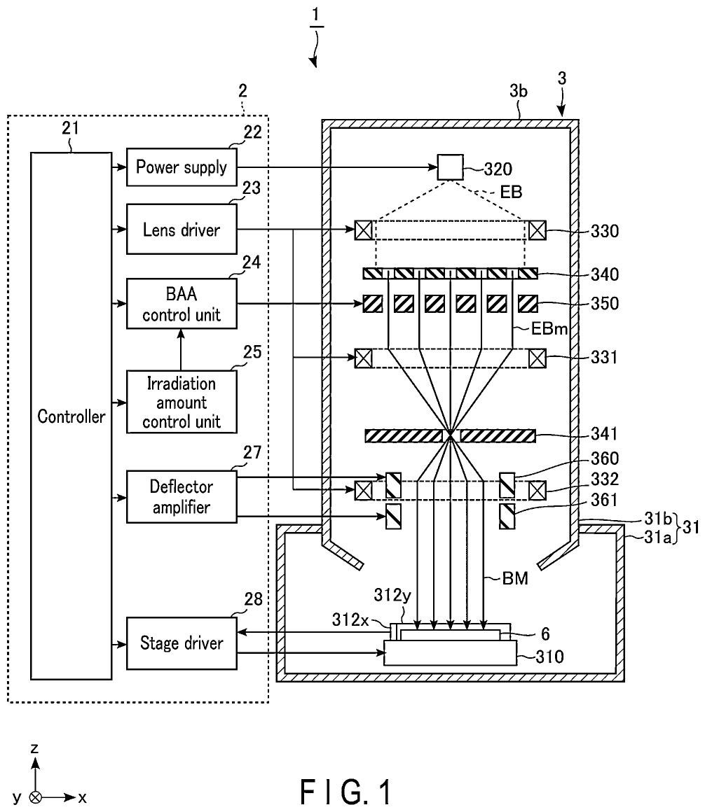

FIG. 1 shows elements (or, configuration) of a writing apparatus 1 according to a first embodiment. As an example, the writing apparatus 1 is a multi-charged particle beam writing apparatus. Some of the elements will be described in detail later.

The writing apparatus 1 includes a control circuit system 2 and a writing mechanism 3. The writing mechanism 3 generates charged particle beams and irradiates a sample 6 with the generated charged particle beams to write a pattern on the sample 6. Examples of the sample 6 include a reticle and a mask coated with resist. The control circuit system 2 controls the operation of the writing mechanism 3. The writing apparatus 1 includes a blanking aperture array system. That is, at least part of the control circuit system 2 and at least part of the writing mechanism 3 constitute the blanking aperture array system.

The writing mechanism 3 includes a vacuum chamber 31. The interior of the vacuum chamber 31 is kept, for example, in vacuum during writing onto the sample 6 by the writing apparatus 1. The vacuum chamber 31 includes a writing chamber 31a and a lens barrel 31b.

The writing chamber 31a has, for example, a rectangular parallelepiped shape and an inner space. The writing chamber 31a holds the sample 6. The writing chamber 31a has an opening in the top surface and is connected to the inner space of the lens barrel 31b in the opening.

The writing apparatus 1 also includes a stage 310 in the writing chamber 31a. The sample 6 is placed on the top surface of stage 310 during writing. The stage 310 can move along the x- and y-axes with the sample 6 held substantially horizontally. Mirrors 312x and 312y are provided on the top surface of the stage 310. The mirror 312x extends along the y axis and the mirror 312y extends along the x-axis. The mirrors 312x and 312y are used as references for detecting of the position of the stage 310.

The lens barrel 31b has a cylindrical shape extending along the z-axis and is formed of, for example, stainless steel. The lower end of the lens barrel 31b is located inside the writing chamber 31a. The writing apparatus 1 further includes, in the lens barrel 31b, an electron gun 320, an illumination lens 330, a reducing lens 331, an objective lens 332, a shaping aperture array plate 340, a limiting aperture array plate 341, a blanking aperture array mechanism (or, blanking aperture array substrate) 350 and deflectors 360 and 361.

The electron gun 320 is located in the upper part of the interior of the lens barrel 31b. The electron gun 320 is, for example, a hot-cathode electron gun. The electron gun 320 includes elements such as a cathode, a Wehnelt electrode and an anode. The Wehnelt electrode surrounds the cathode. Upon receiving a voltage, the electron gun 320 emits an electron beam EB downward along the z-axis (−z direction). The electron beam EB spreads along the xy-plane as it progresses along the z-axis.

The illumination lens 330 is an annular electromagnetic lens located below the electron gun 320 along the z-axis. The illumination lens 330 shapes the electron beam EB, which has reached the illumination lens 330 and spread in the xy-plane, so as to progress in parallel to the z-axis.

The shaping aperture array plate 340 is located below the illumination lens 330 along the z-axis. The shaping aperture array plate 340 has a plurality of apertures to cause part of the electron beam EB incident upon the shaping aperture array plate 340 to pass through the apertures and branch it into a plurality of electron beams EBm.

The blanking aperture array mechanism 350 is located below the shaping aperture array plate 340 along the z-axis (or, in −z direction). The blanking aperture array mechanism 350 individually blanks the electron beams EBm. The blanking aperture array mechanism 350 includes a plurality of apertures located below their respective openings of the shaping aperture array plate 340 along the z-axis (or, in the −z direction), and a blanker provided around each of the apertures. The blanker blanks the electron beam EBm incident upon an aperture for which the blanker is provided.

The reducing lens 331 is an annular electromagnetic lens and is located below the blanking aperture array mechanism 350 along the z-axis (or, in the −z direction). The reducing lens 331 causes the electron beams EBm, which are parallel to each other and have passed through the blanking aperture array mechanism 350, to converge on the center of the aperture of the limiting aperture array plate 341.

The limiting aperture array plate 341 has a plate-like shape extending along the xy-plane and has an aperture in the center of the xy-plane. The aperture is located in the vicinity of a convergence point (crossover point) of the electron beams EBm that have passed through the reducing lens 331. The beams deflected by the blankers provided in the blanking aperture array mechanism 350 cannot pass through the aperture provided in the center of the limiting aperture array plate 341 but are blanked against the limiting aperture array plate 341.

The limiting aperture array plate 341 causes the electron beams EBm to pass through the aperture to shape the electron beams EBm along the xy-plane thereof. In the shaped electron beams EBm, a shot having a selected shape is formed.

The deflector 360 is located below the limiting aperture array plate 341 along the z-axis (or, in the −z direction). The shot-shaped electron beams EBm radiate from the limiting aperture array plate 341 and enter the deflector 360. The deflector 360 includes a plurality of pairs of electrodes. In FIG. 1, only one pair of electrodes is shown to avoid unnecessary complexity of the diagram. Two electrodes of each pair are opposed to each other. A voltage is applied to each of the electrodes, and accordingly the deflector 360 deflects the incident electron beams EBm along the x-axis and/or along the y-axis.

The objective lens 332 is an annular electromagnetic lens and surrounds the deflector 360. The objective lens 332 cooperates with the deflector 360 to focus the electron beams EBm to specific positions of the sample 6.

The deflector 361 is located below the deflector 360 along the z-axis (or, in the −z direction). The electron beams EBm which have passed the deflector 360 enters the deflector 361. The deflector 360 includes a plurality of pairs of electrodes. In FIG. 1, only one pair of electrodes is shown to avoid unnecessary complexity of the diagram. Two electrodes of each pair are opposed to each other. A voltage is applied to each of the electrodes, and accordingly the deflector 360 deflects the incident electron beams EBm along the x-axis and/or along the y-axis.

The control circuit system 2 includes a controller 21, a power supply 22, a lens driver 23, a BAA control unit 24, an irradiation amount control unit 25, a deflector amplifier 27 and a stage driver 28.

The controller 21 controls the power supply 22, lens driver 23, BAA control unit 24, irradiation amount control unit 25, deflector amplifier 27 and stage driver 28. Upon receipt of a signal from, for example, a user of the writing apparatus 1, the controller 21 controls the power supply 22, lens driver 23, BAA control unit 24, irradiation amount control unit 25, deflector amplifier 27 and stage driver 28.

Upon receipt of control data from the controller 21, the power supply 22 applies a voltage to the electron gun 320.

Upon receipt of control data from the controller 21, the lens driver 23 controls the illumination lens 330. Specifically, the lens driver 23 controls the strength of the illumination lens 330 to the electron beam EB, that is, the strength thereof at which the electron beams EB are refracted. The lens driver 23 controls the strength of the illumination lens 330 such that the electron beams EB, which are incident upon the illumination lens 330 from above the illumination lens 330 along the z-axis and spreads along the xy-plane with progress are shaped into electron beams substantially parallel to the z-axis.

Upon receipt of control data from the controller 21, the lens driver 23 also controls the strength of the reducing lens 331. The lens driver 23 controls the strength of the reducing lens 331 such that the electron beams EBm incident upon the reducing lens 331 are caused to converge on the center of the aperture of the limiting aperture array plate 341 from above the reducing lens 331 along the z-axis without being blanked by the blankers of the blanking aperture array mechanism 350.

Upon receipt of control data from the controller 21, the lens driver 23 further controls the strength of the objective lens 332. The lens driver 23 controls the strength of the objective lens 332 such that the electron beams BM incident upon the objective lens 332 from above the objective lens 332 along the z-axis are caused to converge on the top surface of the sample 6. Note that the lens driver 23 may reduce the electron beams BM.

The BAA control unit 24 receives BAA control data from the controller 21 to control the blanking aperture array mechanism 350.

The irradiation amount control unit 25 receives control data from the controller 21 to generate irradiation amount control data. The irradiation amount control unit 25 supplies the generated irradiation amount control data to the BAA control unit 24 to control the amount of irradiation of the electron beams BM to the sample 6 through the BAA control unit 24.

The deflector amplifier 27 receives control data from the controller 21 to generate a control signal for controlling each of the deflectors 360 and 361. The generated control signal is supplied to each of the deflectors 360 and 361. The signal for the deflector 360 specifies a potential difference between two electrodes of each pair of the deflectors 360. Similarly, the signal for the deflector 361 specifies a potential difference between two electrodes of each pair of the deflectors 361. The deflector amplifier 27 generates a signal for the deflector 360 such that the deflector 360 receives a voltage that deflects the electron beams EBm by an amount and/or a direction specified by the controller 21. Similarly, the deflector amplifier 27 generates a signal for the deflector 361 such that the deflector 361 receives a voltage that deflects the electron beam EBms by an amount and/or a direction specified by the controller 21.

The stage driver 28 measures the locations of the mirrors 312x and 312y using a means such as a laser sensor (not shown) to detect the location of the stage 310. The stage driver 28 receives control data from the controller 21 to drive the stage 310. When the stage 310 is driven, the sample 6 moves to a desired position.

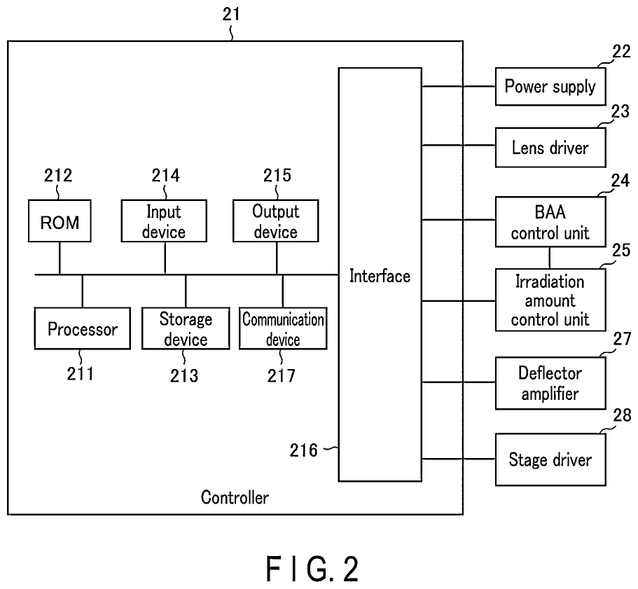

FIG. 2 shows a configuration of the controller 21 according to the first embodiment and in particular, a hardware configuration thereof. As shown in FIG. 2, the controller 21 includes a processor 211, a read only memory (ROM) 212, a storage device 213, an input device 214, an output device 215, an interface 216 and a communication device 217.

The ROM 212 stores programs for controlling the processor in a non-volatile manner. The storage device 213 includes a volatile memory, a nonvolatile memory and/or a hard disk to store data. The processor 211 is, for example, a central processing unit (CPU), and executes programs, which are stored in the ROM 212 and loaded into the storage device 213, to perform a variety of operations. In accordance with the programs, the processor 211 controls the storage device 213, input device 214, output device 215, interface 216 and communication device 217. The programs are configured to allow the controller 21, especially the processor 211, to perform operations described later as operations of a variety of functional blocks.

The input device 214 includes one or more of a keyboard, a mouse and a touch panel to allow the user of the writing apparatus 1 to input instructions and/or parameters. The output device 215 includes a display to present various items of information to the user of the writing apparatus 1. The interface 216 is responsible for communications between the controller 21 and each of the power supply 22, lens driver 23, BAA control unit 24, irradiation amount control unit 25, deflector amplifier 27 and stage drive 28.

The communication device 217 is configured to communicate with an external device of the writing apparatus 1. The communication device 217 is, for example, coupled to the external device of the writing apparatus 1 wirelessly and/or by wire to allow data to be transmitted and received to and from the external device of the writing apparatus 1.

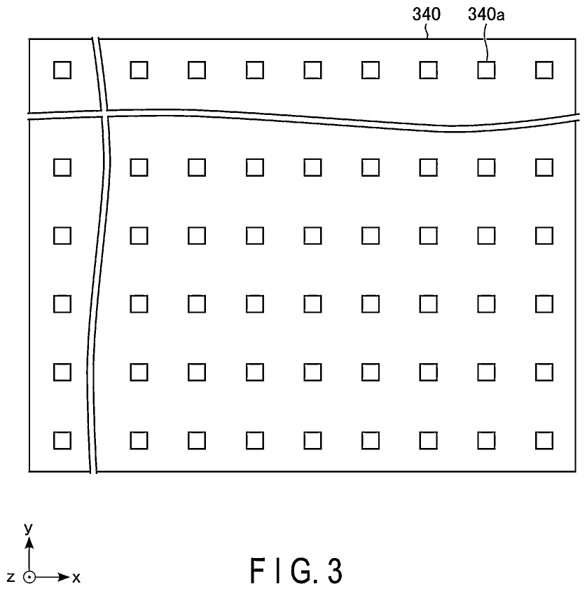

FIG. 3 schematically shows a structure of the shaping aperture array plate 340 of the first embodiment along the xy-plane. As shown in FIG. 3, the shaping aperture array plate 340 expands along the xy-plane and has, for example, a rectangular shape. The shaping aperture array plate 340 contains, for example, silicon as a base, and the surface of the base is covered with a thin film. The thin film is, for example, chromium and can be formed by plating or sputtering. The shaping aperture array plate 340 has a plurality of apertures 340a. The apertures 340a penetrate two opposing surfaces, namely, the top and bottom surfaces of the shaping aperture array plate 340 along the z-axis of the plate 340. The apertures 340a are arranged in a matrix along the x and y axes, for example. The apertures 340a are each, for example, a square and have substantially the same shape.

The electron beams EB emitted from the electron gun 320 are shaped to be parallel along the z-axis by the illumination lens 330 and enter the top surface of the shaping aperture array plate 340. Some of the electron beams EB that has entered are shielded by the shaping aperture array plate 340, and the remaining electron beams pass through the apertures 340a. With such selective shielding and passing of the electron beams EB, the electron beams EB are divided into a plurality of electron beams EBm that travel downward along the z-axis.

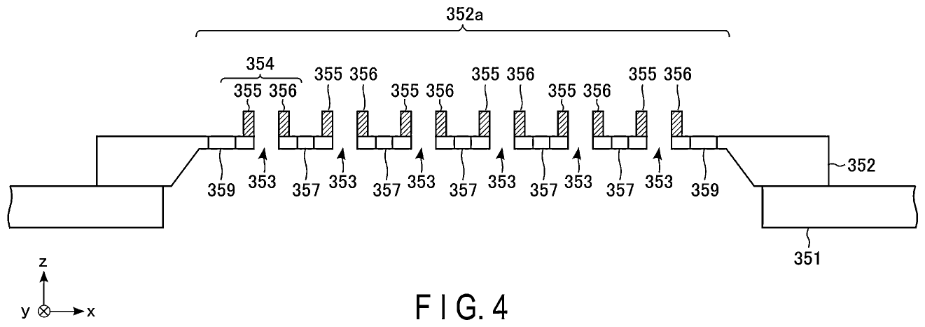

FIG. 4 shows a structure of the blanking aperture array mechanism 350 of the first embodiment along the xz plane. As shown in FIG. 4, the blanking aperture array mechanism 350 includes a base 351. The base 351 expands along the xy-plane.

A substrate 352 is provided on the top surface of the base 351. The substrate 352 is made of, for example, a semiconductor such as silicon. The substrate 352 is located on the top surface of the substrate 351 at its bottom edge, and a central portion 352a thereof is thinner than a edge portion thereof. The substrate 352 includes a plurality of apertures 353 in the central portion 352a. Each of the apertures 353 extends over the top and bottom surfaces of the substrate 352. The apertures 353 are arranged in the xy-plane. The apertures 353 are located below the apertures 340a of the shaping aperture array plate 340 along the z-axis of the apertures 340a. The shape of each of the apertures 353 is similar to, for example, that of each of the apertures 340a in the xy-plane, but the former is slightly larger than the latter. In addition, the center of each of the apertures 353 substantially coincides with that of each of the apertures 340a on the xy-plane. The electron beams EBm, which have passed through the apertures 340a of the shaping aperture array plate 340, are caused to pass through the apertures 353.

The blanking aperture array mechanism 350 also includes a plurality of electrode pairs 354. Each of the electrode pairs 354 is provided for one aperture 340a and includes electrodes 355 and 356 to function as blankers. The electrodes 355 and 356, for example, contain copper or are made of copper. The electrodes 355 and 356 of each electrode pair 354 are separated from each other and sandwich one aperture 353 that is provided with the electrode pair 354.

A register 357 is provided in a portion of the substrate 352 between adjacent electrode pairs 354 (i.e., between the electrode 355 of an electrode pair 354 and the electrode 356 of an adjacent electrode pair 354). The register 357 is provided for one electrode pair 354. The register 357 receives a variety of control signals, holds the received control signals, and applies a voltage to the one electrode pair 354 based on the control signals. The register 357 includes elements such as a plurality of transistors and resistors formed on the substrate 352.

A serial/parallel conversion circuit (S/P conversion circuit) 359 is provided at either end of the central portion 352a of the substrate 352. The S/P conversion circuit 359 serially receives control data DLS from a BAA control unit 24, divides the received control data DLS into a plurality of control data items DL, and outputs the control data items DL in parallel. The S/P conversion circuit 359 includes elements such as a plurality of transistors and resistors formed on the substrate 352.

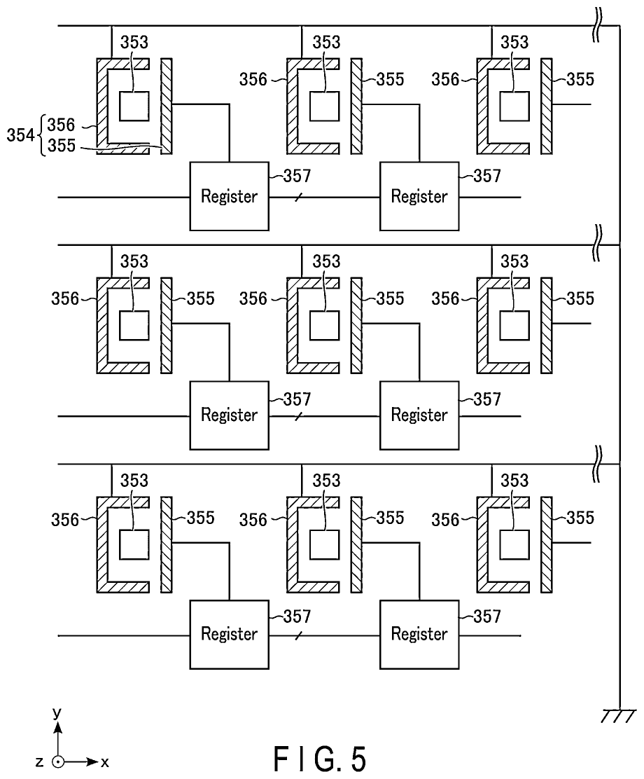

FIG. 5 shows a structure of the blanking aperture array mechanism 350 of the first embodiment along the xy-plane. As shown in FIG. 5, each electrode 356 is shaped like a letter “U” having three sides. The three sides of the electrode 356 extend along three sides of the aperture 353 surrounded by the electrode 356. In the example shown in FIG. 5, two sides of the three sides are parallel to the x-axis of the aperture 353 and the remaining one side is parallel to the y-axis of the aperture 353.

Each electrode 355 extends along one of the sides of the corresponding aperture 353 along which the electrode 356, which is paired with the electrode 355, does not extend. In the structure shown in FIG. 5, each electrode 355 extends along the right one of the two sides of the aperture 353 which are parallel to the y-axis.

The electrodes 356 are grounded (or, coupled to the ground). Each electrode 355 is electrically coupled to its corresponding register 357.

The registers 357 receive a variety of control signals as described above. The control signals include clock signals and control data items DL. The control signals are supplied from the BAA control unit 24. Each register 357 is coupled to the node of an internal power supply potential VCC (e.g., 5 V).

Each electrode 356 is coupled to the node of a common (or, ground) potential VSS (e.g., 0 V).

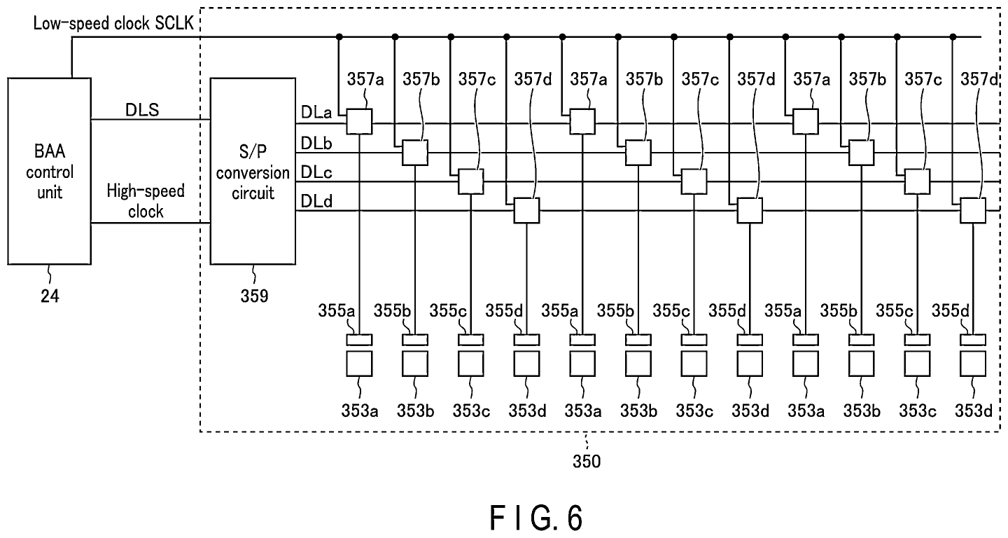

FIG. 6 is a circuit diagram showing the blanking aperture array mechanism 350 of the first embodiment and also showing related elements. In FIG. 6, only one S/P conversion circuit 359 and its associated elements are shown as representatives.

As shown in FIG. 6, the S/P conversion circuit 359 is coupled to the BAA control unit 24 to receive control data DLS and a high-speed clock (high-speed clock signal) from the BAA control unit 24. The transfer of the control data DLS from the BAA control unit 24 to the S/P conversion circuit 359 is performed via a signal line having a width of 1 bit.

As described above, the S/P conversion circuit 359 is a serial/parallel conversion circuit that divides the received control data DLS into a plurality of control data items DL and outputs the control data items DL in parallel. FIG. 6 shows an example in which the S/P conversion circuit 359 outputs parallel control data items DL of 4 bits in total. For example, the S/P conversion circuit 359 outputs a first bit of the consecutive 4 bits in the control data DLS as control data item DLa, outputs a second bit thereof as control data item DLb, outputs a third bit thereof as control data item DLC, and outputs a fourth bit thereof as control data item DLd. Thus, the control data items DLa, DLb, DLc and DLd are output in sequence for every consecutive four bits.

The S/P conversion circuit 359 transfers the control data items DL to their respective registers 357.

The input of one of the registers 357 receives control data item DLa from the S/P conversion circuit 359. The register 357 that receives the control data item DLa from the S/P conversion circuit 359 is referred to as a register 357a. The output of the register 357a is coupled to the input of another register 357. Similarly, the output of each register 357a is coupled to the input of another register 357a. The register 357a receives a low-speed clock (low-speed clock signal) SCLK from the BAA control unit 24. The low speed clock SCLK has a period that is longer than that of the high-speed clock. The low-speed clock CLK is synchronized with a duration of each serial data transferred by the control data items DL. This duration may hereinafter be referred to as a data period. The register 357a fetches data, which is received by its own input, using the rise or fall of the low-speed clock (hereinafter referred to as an edge) as a trigger. The register 357a also outputs the held data using the edge of the low-speed clock SCLK as a trigger. Accordingly, in synchronization with the edge of the low-speed clock SCLK, data held in the register 357a closer to the S/P conversion circuit 359 is transferred from the S/P conversion circuit 359 to its far adjacent register 357a. Thus, each register 357a holds the received data and outputs the held data to another register 357a coupled in series thereto. That is, a set of series-coupled registers 357a is formed as a shift register 3571a.

Each register 357a is coupled to one electrode 355, which is to be controlled by the register 357a, via a level shifter (not shown). The electrode 355 coupled to the register 357a via the level shifter is referred to as a electrode 355a. Based on the held data, each register 357a supplies a voltage whose magnitude is shifted by the level shifter to the electrode 355a to which the register 357a is coupled. The aperture 353 partially surrounded by each electrode 355a is referred to as an aperture 353a.

Similarly to the register 357 that receives the control data item DLa in sequence from the S/P conversion circuit 359 is referred to as the register 357a, the registers 357 that receive the control data items DLb, DLC and DLd are referred to as registers 357b, 357c and 357d. Similarly to the electrode 355 that receives a voltage from the register 357a is referred to as an electrode 355a, the electrode 355 that receives the voltages from the registers 357b, 357c and 357d are referred to as electrodes 355b, 355c and 355d. In addition, similarly to the aperture 353 partially surrounded by each electrode 355a is referred to as an aperture 353a, the aperture 353 partially surrounded by electrodes 354b, 354c and 354d is referred to as aperture 353b, 353c and 353d.

The descriptions of the control data DLa, register 357a and electrode 355a with alphabetical subscript “a” replaced by alphabetical subscript “b” apply to those of the control data DLb, register 357b and electrode 355b. Similarly, the descriptions of the control data DLa, register 357a and electrode 355a with alphabetical subscript “a” replaced by alphabetical subscript “c” apply to those of the control data DLC, register 357c and electrode 355c. Similarly, the descriptions of the control data DLa, the register 357a and electrode 355a with alphabetical subscript “a” replaced by alphabetical subscript “d” apply to those of the control data DLd, register 357d and electrode 355d.

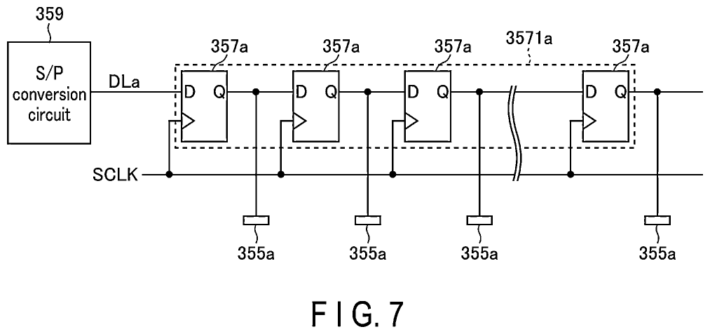

FIG. 7 shows elements of one shift register 3571 of the first embodiment and coupling of the elements. FIG. 7 also shows, as an example, a shift register 3571a, which transfers the control data item DLa. As shown in FIG. 7, each register 357a is, for example, a D-type flip-flop.

The shift register includes n (n is a natural number) D-type flip-flops 357a. The D input of the D-type flip-flop 357a of the first stage receives a control data item DLa from the S/P conversion circuit 359. For all cases where i is 1 to n (i is a natural number less than or equal to n), the Q output of the flip-flop of the i-th stage is coupled to the D input of the flip-flop 357 of the (i+1)-th stage. The Q output of each flip-flop 357a is coupled to one control-target electrode 355a. The clock input of each flip-flop 357a receives a low-speed clock SCLK.

FIG. 7 shows a shift register 3571a, which transfers the control data item DLa, but the same applies to a shift register that transfers the control data items DLb, DLC and DLd. That is, the description made with reference to FIG. 7 with alphabetical subscript “a” replaced with alphabetical subscripts “b,” “c” and “d” apply to the descriptions of the shift registers 3571b, 3571c and 3571d, which transfer control data items DLb, DLC and DLd, respectively.

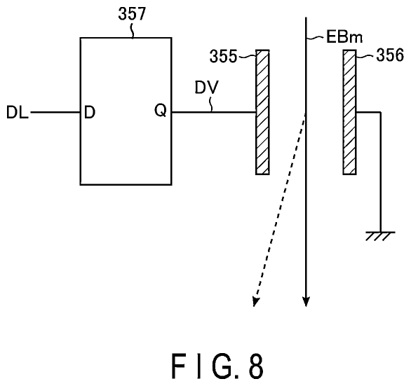

As shown in FIG. 8, the flip-flop 357 applies a driving voltage DV whose magnitude is based on its currently held control data DL to the electrode 355 coupled to the Q output of the flip-flop 357. That is, the control data DL held in each flip-flop 357a instructs the flip-flop 357a to apply a low voltage or high voltage driving voltage DV to the electrode 355a coupled to the flip-flop 357a. The low voltage has, for example, the magnitude of a common potential VSS (e.g., 0 V). The high voltage has, for example, the magnitude of an internal power supply potential VCC. The control data DL instructs the flip-flop 357a to apply a low driving voltage DV by, for example, “0” data or “L” level. The control data DL instructs the application of a high driving voltage DV by, for example, “1” data or “H” level.

If the control data DL in the flip-flop 357 instructs the flip-flop 357 to apply a low driving voltage DV, the low driving voltage DV is output from the Q output of the flip-flop 357. In this case, there is no potential difference between the electrodes 355 and 356, and consequently, no electric field is generated. Thus, the electron beam EBm is not bent (or, blanked) by the electrodes 355 and 356, and as shown by the solid line, it travels in the same direction as when it enters an area between the electrodes 355 and 356.

On the other hand, if the control data DL in the flip-flop 357 instructs the flip-flop 357 to apply a high driving voltage DV, the high driving voltage DV is output from the Q output of the flip-flop 357. In this case, a potential difference occurs between the electrodes 355 and 356, resulting in an electric field. Thus, the electron beam EBm is bent (or, blanked) by the electrodes 355 and 356 and, as indicated by the dashed line, it travels in a direction other than when it enters an area between the electrodes 355 and 356.

As described above, when a certain register 357 is normal and the control data DL held in this register 357 instructs the register 357 to apply a high voltage, a high voltage is applied to the electrode 355 coupled to the register 357 and thus the electron beam EBm is bent. When a certain register 357 is not normal to the contrary, if the control data DL held in this register 357 instructs the register 357 to apply a high voltage, the high voltage is not applied to the electrode 355 coupled to the register 357, and the electron beam EBm is not bent. The register 357 includes a plurality of transistors T, as will be described in detail, and a state in which the register 357 is not normal corresponds to a case in which the register 357 includes a transistor T that is not normal. If a transistor T included in the register 357 is not normal, its performance is degraded, and the transistor T does not exhibit the same characteristics as the original ones (for example, the characteristics of the transistor T which has been just manufactured).

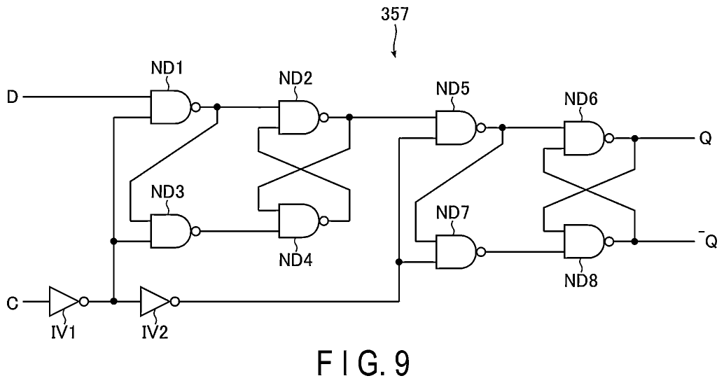

FIG. 9 shows an example of elements of the D-type flip-flop 357 of the first embodiment and coupling of the elements. The D-type flip-flop 357 may, by way of example, include the elements and their coupling shown in FIG. 9. As shown in FIG. 9, the D-type flip-flop 357 includes NAND gates ND1, ND2, ND3, ND4, ND5, ND6, ND7 and ND8, and inverters (or, NOT circuits) IV1 and IV2.

The input of the inverter IV1 functions as the clock input of the D-type flip-flop 357. The output of the inverter IV1 is coupled to the input of the inverter IV2.

The first input of the NAND gate ND1 functions as the D input of the D-type flip-flop 357. The second input of the NAND gate ND1 is coupled to the output of the inverter IV1. The output of the NAND gate ND1 is coupled to the first input of the NAND gate ND2. The output of the NAND gate ND1 is also coupled to the first input of the NAND gate ND3. The second input of the NAND gate ND3 is coupled to the output of the inverter IV1. The output of the NAND gate ND3 is coupled to the first input of the NAND gate ND4. The second input of the NAND gate ND4 is coupled to the output of the NAND gate ND2. The output of the NAND gate ND4 is coupled to the second input of the NAND gate ND2.

The output of the NAND gate ND2 is also coupled to the first input of the NAND gate ND5. The second input of the NAND gate ND5 is coupled to the output of the inverter IV2. The output of the NAND gate ND5 is coupled to the first input of the NAND gate ND6. The output of the NAND gate ND5 is also coupled to the first input of the NAND gate ND7. The second input of the NAND gate ND7 is coupled to the output of the inverter IV2. The output of the NAND gate ND7 is coupled to the first input of the NAND gate ND8. The second input of the NAND gate ND8 is coupled to the output of the NAND gate ND6. The output of the NAND gate ND8 is coupled to the second input of the NAND gate ND6.

The output of the NAND gate ND6 functions as the Q output of the D-type flip-flop 357. The output of the NAND gate ND8 functions as the ⁻Q output of the D-type flip-flop 357. The symbol “⁻” indicates the logic of inversion of a signal whose name does not include the symbol “⁻”.

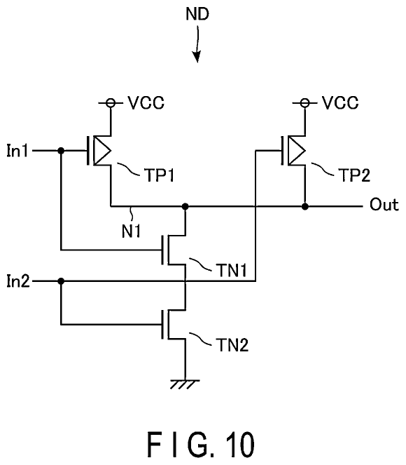

The NAND gates ND1 to ND8 may include any elements and coupling as long as they function as NAND gates. An example thereof is described below. FIG. 10 shows an example of elements of the NAND gate ND (ND1 to ND8) of the first embodiment and coupling of the elements.

As shown in FIG. 10, the NAND gate ND includes p-type metal oxide silicon field effect transistors (MOSFETs) TP1 and TP2 and n-type MOSFETS TN1 and TN2. The transistors TP1 and TP2 are coupled in parallel between the node of the internal power supply potential VCC and the node N1. The node N1 functions as the output Out of the NAND gate ND. The transistors TN1 and TN2 are coupled in series between the node N1 and the node of the ground potential VSS. The respective gates of the transistors TP1 and

TN1 are coupled to each other and function as the first input In1 of the NAND gate ND. The respective gates of the transistors TP2 and TN2 are coupled to each other and function as the second input In2 of the NAND gate ND.

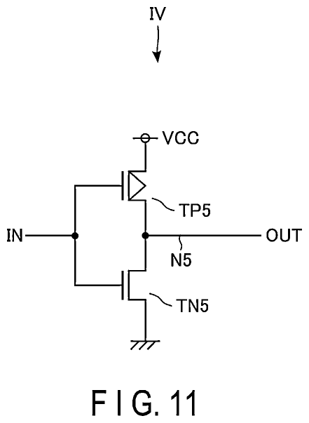

The inverters IV1 and IV2 may include any elements and coupling as long as they function as inverters. An example thereof is described below. FIG. 11 shows an example of elements of the inverter IV (IV1 and IV2) of the first embodiment and coupling of the elements.

As shown in FIG. 11, the inverter IV includes a p-type MOSFET TP5 and an n-type MOSFET TN5. The transistor TP5 is coupled between the node of the internal power supply potential VCC and the node N5. The node N5 functions as an output OUT of the inverter IV. The transistor TN5 is coupled between the node N5 and the node of the ground potential VSS. The respective gates of the transistors TP5 and TN5 are coupled to each other and function as the input IN of the inverter IV.

### 1.2. Operation

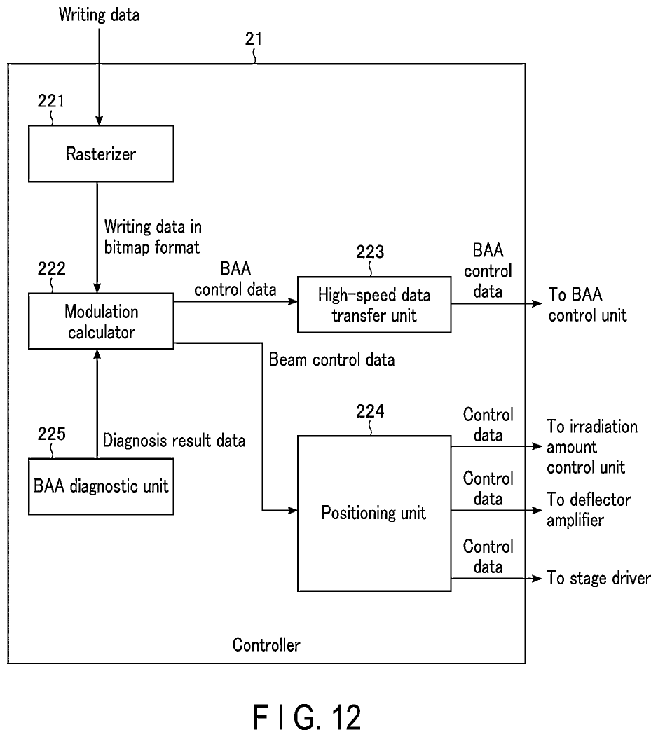

FIG. 12 shows functional blocks of the controller 21 of the first embodiment. The controller 21 operates during the operation of the writing apparatus 1 as including the functional blocks shown in FIG. 12 and. Each of the functional blocks can be implemented by the processor 211 executing programs, as has been described with reference to FIG. 2. Some of the functional blocks may be implemented by hardware.

As shown in FIG. 12, the controller 21 includes a rasterizer 221, a modulation calculator 222, a high-speed data transfer unit 223, a positioning unit 224 and a BAA diagnostic unit 225.

In response to, for example, the input from the user of the writing apparatus 1, the rasterizer 221 receives, for example, writing data in a vector format from an external device and rasterizes the writing data to generate writing data in a bitmap format.

The modulation calculator 222 receives the writing data from the rasterizer 221. Based on the writing data, the modulation calculator 222 generates control data to control each element for writing. The generated control data contains BAA control data and beam control data. The BAA control data is used for blanking control in the blanking aperture array mechanism 350 and supplied to the high-speed data transfer unit 223. The BAA control data specifies a register 357 to output a high driving voltage DV and also specifies the magnitude of the driving voltage DV. Hereinafter, the register 357 that outputs the driving voltage DV specified by the BAA control data may be referred to as a selected register 357s. The beam control data is used to control the position of beams and the irradiation amount thereof, and is supplied to the positioning unit 224. The modulation calculator 222 takes into consideration data supplied from the BAA diagnostic unit 225 (described later) to generate the BAA control data.

The high-speed data transfer unit 223 supplies the BAA control data to the BAA control unit 24 via the interface 216 (not shown). The positioning unit 224 generates a variety of control data items based on the beam control data. The generated control data items are supplied to the irradiation amount control unit 25, deflector amplifier 27 and stage driver 28 via the interface 216.

In response to the programs and the input from the user of the writing apparatus 1, the BAA diagnostic unit 225 performs a process for BAA diagnosis and supplies data indicating a result of the diagnosis to the modulation calculator 222. The modulation calculator 222 generates BAA control data using the diagnosis result data. Next is a description of the operation of the BAA diagnostic unit 225.

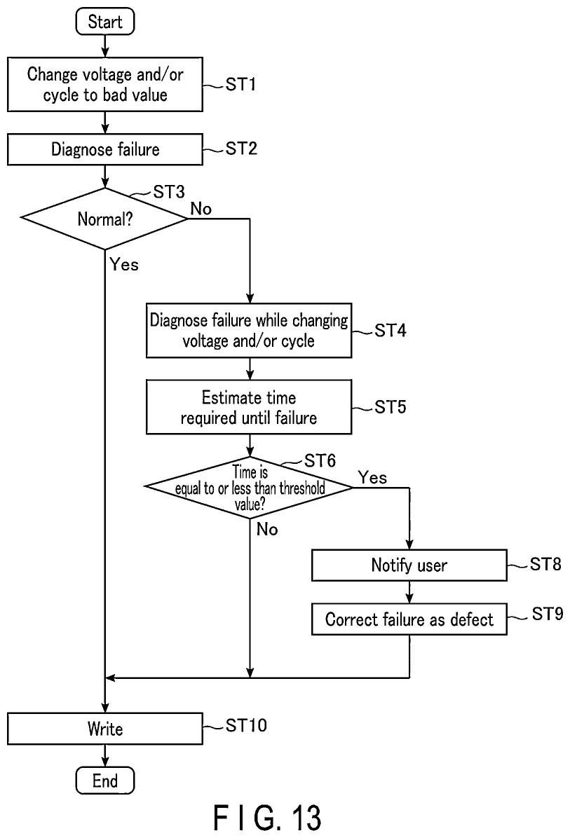

FIG. 13 shows a flow of an operation performed by the writing apparatus 1 according to the first embodiment. More specifically, FIG. 13 shows a flow of an operation for writing and preparation for writing. The flow of FIG. 13 is started, for example, by a user's operation of the writing apparatus 1. Some of the steps in the flow will be described in detail below.

In some steps from step ST1, the BAA diagnostic unit 225 specifies a register 357 that is expected to fail in the near future. Specifically, in step ST1, the BAA diagnostic unit 225 instructs the modulation calculator 222 to use conditions that are worse than a normally used condition for controlling the blanking aperture array mechanism 350, especially for transmitting the control data DL. The normally used condition is one used for the blanking aperture array mechanism 350 that is not degraded, such as a condition used for the blanking aperture array mechanism 350 in the state immediately after the writing apparatus 1 is manufactured. The subjects changed to worse conditions include, for example, the magnitude of the “H”-level control data DL, and the output period of a set of the cycle of the low-speed clock SCLK (which may be referred to as a low-speed clock cycle hereinafter) and a data cycle. A worse condition for the “H” level of the control data DL is an “H” level voltage which has a smaller magnitude than the “H” level voltage under normally used conditions but still causes the register (flip-flop) 357 to hold an “H” level (i.e., “1” data) when received by each register (flip-flop) 357. A worse condition for the set of a low-speed clock cycle and a data cycle is a shorter output period for the low-speed clock cycle and data cycle.

The BAA diagnostic unit 225 tries to specify a register 357 that does not normally operate under the control of the blanking aperture array mechanism 350 under the condition set in step ST1. That is, the BAA diagnostic unit 225 determines (or confirms or checks) whether the register 357 is operating normally. The register 357, especially the transistor T in the register 357, may be decreased in its performance by degradation. Even if the register 357 whose performance is degraded is operated at a certain time under normal conditions, that is, under conditions applied when the register 357 is not degraded, it increases in its degradation in the near future and may not operate normally under normal conditions. For this register 357, the BAA diagnostic unit 225 intentionally uses conditions that are worse than the normal conditions, and can detect it based on whether or not a normal operation can be performed under the worse conditions. The BAA diagnostic unit 225 can detect the register 357 whose degradation is less as worse conditions are used. The bad conditions used depend upon how much degradation is to be detected. The bad conditions used can be determined, for example, by the selection or input of a value by the user of the writing apparatus 1. For example, the worst conditions can be used to detect the degradation with the highest sensitivity. The worst conditions include, for example, a condition that the transistor T is turned indicated by design and/or specifications. For example, it is the worst condition that a threshold voltage is the lowest in terms of design and/or specifications to turn on the transistor T, and/or it is the worst condition that the clock and data periods are the shortest in terms of design and/or specifications that allow the shift register 3571 to capture and hold data normally.

In step ST2, the BAA diagnostic unit 225 diagnoses a failure of the blanking aperture array mechanism 350, especially the register 357, under the conditions determined to be used. Specifically, the BAA diagnostic unit 225 instructs the modulation calculator 222 to emit and blank electron beams under the conditions determined to be used. Upon receiving the instructions, the modulation calculator 222 generates BAA control data which controls the register 357 under the conditions. The generated BAA control data is transmitted from the BAA control unit 24 to the blanking aperture array mechanism 350. The BAA diagnostic unit 225 checks the state of the electron beams EBm during the operation of the blanking aperture array mechanism 350 based on the BAA control data. That is, the BAA diagnostic unit 225 indirectly determines whether a certain selected register 357s is operating normally by observing whether the electron beams EBm, which pass between the electrode 355 coupled to the selected register 357s and the electrode 356 paired with the electrode 355, are blanked. If the electron beams EBm are blanked, the BAA diagnostic unit 225 determines that the selected register 357s to be checked is operating normally and thus determines that the selected register 357s does not fail (or, it is operating normally). If the electron beams EBm are not blanked, the BAA diagnostic unit 225 determines that the selected register 357s to be checked is not operating normally and thus the BAA diagnostic unit 225 determines that the selected register 357s fails (or, it is not operating normally). The BAA diagnostic unit 225 diagnoses all the registers 357, for example. The BAA diagnostic unit 225 stores information that specifies the register 357 determined to fail in the storage device 213, for example.

In step ST3, the BAA diagnostic unit 225 determines whether the blanking aperture array mechanism 350 is normal. This determination is made, for example, based on step ST2 in which the BAA diagnostic unit 225 determines that none of the registers 357 fail. If the BAA diagnostic unit 225 determines the blanking aperture array mechanism 350 is normal (Yes in step ST3), preparations for writing are completed. In this case, the writing apparatus 1 uses, for example, the output device 215 to notify the user that the failure diagnosis has been completed and that no failure has been detected. Upon receipt of the notification, the user performs writing (step ST10).

If the BAA diagnostic unit 225 determines in step ST3 that the blanking aperture array mechanism 350 is not normal (No in step ST3), the process proceeds to step ST4. In some steps subsequent to step ST4, the BAA diagnostic unit 225 further diagnoses some or all of the registers 357 which are determined in step ST2 as failed ones. Hereinafter, the register 357 to be diagnosed in step ST4 will be referred to as a target register 357t.

Specifically, in step ST4, the BAA diagnostic unit 225 determines whether the target register 357t normally operates by repeatedly changing, for each loop, the magnitude of the “H” level voltage of the control data DL input to the target register 357t, that is, the control data DL input to the shift register 3571 including the target register 357t. The “H” level voltage is increased, for example, from the “H” level voltage used in step ST2 in certain increments each time the number of loops is increased. In a certain loop in the loop repetition process, the target register 357t normally operates. The BAA diagnostic unit 225 holds the magnitude of the “H” level voltage in the storage device 213 in association with the target register 357t. The “H” level voltage in the case where the target register 357t normally operates for the first time in a certain loop in the loop repetition process is closest to the worst conditions set in step ST1, for example, the lowest design and/or specifications threshold voltage at which the transistor T is turned on.

Instead of or in addition to changing the magnitude of the “H” level voltage, the BAA diagnostic unit 225 can determine whether the target register 357t operates normally while changing the cycle of the low-speed clock SCLK and that of the control data DL for each loop. As described above, the cycle of the low-speed clock SCLK and that of the control data DL are synchronized with each other. Hereinafter, the cycle of the low-speed clock SCLK and that of the control data DL may be referred to simply as the cycle of the low-speed clock SCLK (or, the low-speed clock cycle). The “cycle of the low-speed clock SCLK” and “data cycle of the control data DL” can be replaced with each other in the following descriptions. The low-speed clock cycle is, for example, lengthened from the low-speed clock cycle used in step ST2 in certain increments each time the number of loops is increased. In a certain loop in the loop repetition process, the target register 357t normally operates. The BAA diagnostic unit 225 holds the low-speed clock cycle in the storage device 213 in association with the target register 357t. The low-speed clock cycle in the case where the target register 357t normally operates for the first time in a certain loop in the loop repetition process is closest to the worst conditions set in step ST1, for example, the shortest cycle in design and/or specifications of the low-speed clock cycle and the data cycle.

The BAA diagnostic unit 225 can apply the above-described diagnosis for the particular target register 357t to all of the other target registers 357t. The BAA diagnostic unit 225 can diagnose all the target registers 357t in parallel, that is, in a common loop. Step ST4 will be further described later.

In step ST5, the BAA diagnostic unit 225 estimates the expected time to be taken by each of the target registers 357t to fail, based on the information obtained in step ST4. That is, the magnitude of the “H” level voltage for normally operating a target register 357t is correlated with the degree of degradation of the target register 357t. In addition, the degree of degradation is correlated with the time from the present time until the target register 357t stops operating under normal conditions due to the progress of degradation associated with future use, that is, the time until the target register 357t fails. Using this fact, the BAA diagnostic unit 225 estimates the time from the present time until the failure of the target register 357t based on the magnitude of the “H” level voltage for normally operating the target register 357t.

As in step ST4, instead of or in addition to the estimation of the time until the failure based on the magnitude of the “H” level voltage, the BAA diagnostic unit 225 can estimate the time until the failure of the target register 357t based on the low-speed clock cycle. That is, the low-speed clock cycle for normally operating the target register 357t is correlated with the degree of degradation of the register 357t. The degree of degradation is correlated with the time from the present time until the failure of the register 357t due to the progress of degradation associated with future use. Using this fact, the BAA diagnostic unit 225 estimates the time from the present time until the failure of the target register 357t based on the low-speed clock cycle for operating the target register 357t normally.

Step ST5 will be further described later.

In step ST6, the BAA diagnostic unit 225 determines whether the estimated failure time for each of the target registers 357t is equal to or less than a certain threshold value (or, reference time). During writing, even if a failure occurs in a component of the writing apparatus 1, the failed component cannot be replaced, while one writing takes time. It is thus required that no components of the writing apparatus 1 fail during the writing. If the estimated failure times of all the target registers 357t are longer than time required for one writing, a target register 357t can be prevented from failing during the next writing. Based on this, the threshold value may be set as, for example, time required for one writing. There is a possibility that the prediction of the estimated failure time is wrong to cause a failure in the target register 357t within the time required for one writing. In consideration of this, the threshold value may be set to a time that is longer than the time required for one writing, such as a time required for two writings, with a little margin in the estimated failure time. Alternatively, the threshold value can be set to a time period determined based on a plan for writing, during which the user wishes to avoid failures occurring. The threshold value may, for example, be entered by the user in advance, particularly before the start of the flow of FIG. 13.

If the estimated failure time of all the target registers 357t is not equal to or less than the threshold value (or, exceeds the threshold value) (No in step ST6), the process proceeds to step ST10.

If the estimated failure time of any one of the target registers 357t is equal to or less than the threshold value (Yes in step ST6), the process proceeds to step ST8. In step ST8, the BAA diagnostic unit 225 uses, for example, the output device 215 to notify the user that the estimated time required until the failure of the blanking aperture array mechanism 350 is equal to or less than the threshold value. The notification may include, for example, information that specifies a register 357 whose estimated failure time exceeds the threshold value.

In step ST9, the user corrects as a defect the register 357 whose estimated failure time is equal to or less than the threshold value. This correction includes, for example, increasing the “H” level voltage of the control data DL or lengthening the low-speed clock cycle (and the data cycle of the control data DL) (or, lowering the frequency). Thus, the operation of the register 357 is ensured. Alternatively, the correction includes replacing the blanking aperture array mechanism 350. The replacement ensures the operation of the register 357. Alternatively, if only the register 357 is replaceable, a register 357 having the estimated failure time that is equal to or less than the threshold value is replaced. The replacement ensures the operation of the register 357.

In step ST9, the following correction is also possible. That is, if a register 357 fails, its Q output does not depend upon the control data DL but is fixed at a level corresponding to the failure. Thus, the presence or absence of blanking for beams whose blanking is controlled by the Q output of the failed register 357 is fixed. Thus, the beams are used as ones which are always blanked or not always blanked, and the operation by the beams whose presence or absence of blanking is fixed is corrected by beams controlled by another register 357 that is normally operating.

As a countermeasure against the possibility of failure in step ST9 of FIG. 13, for example, writing may be performed to correct the failure by normal beams as conventionally known constant on/off beams because the deflection of output of a failed shift register is fixed.

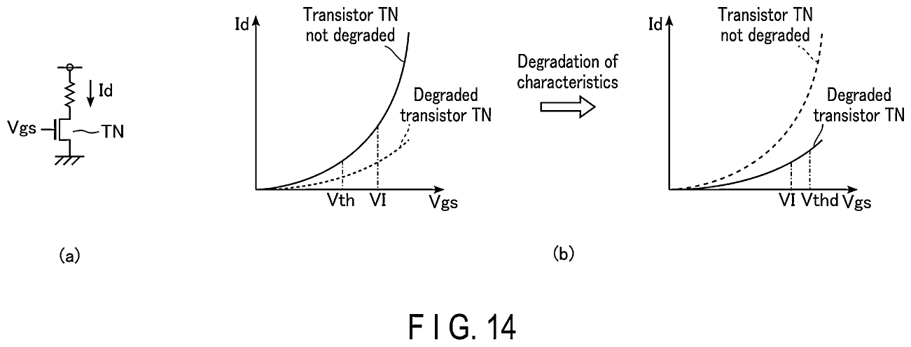

Step ST1 will be further described with reference to FIG. 14. FIG. 14 shows an example of characteristics of the transistor T of the first embodiment before and after the degradation of the characteristics. As an example, FIG. 14 shows the relationship between the drain current and the gate to source voltage of the n-type MOSFET TN (e.g., transistor TN1, TN2 or TN5) of the register 357. As shown in a section (a) of FIG. 14, the transistor TN causes different drain currents Id to flow based on the magnitude of the gate to source voltage Vgs.

A section (b) of FIG. 14 shows the characteristics of the transistor TN before and after the degradation of the characteristics. As shown in the left part of section (b) of FIG. 14, the threshold voltage of the transistor TN has a certain magnitude Vth before the degradation of the characteristics of the transistor TN. If a voltage VI (>Vth) is applied between the gate and source of the transistor TN, the transistor TN is turned on. The voltage VI is a voltage applied to the transistor TN under normal conditions and will be referred to as a standard voltage VI. Assume that the characteristics of the transistor TN are degraded to have the characteristics indicated by the solid line in the right part of FIG. 14B. The transistor TN has a threshold voltage Vthd that is higher than the threshold voltage Vth before degradation, and the threshold voltage Vthd is higher than the standard voltage VI. Therefore, the transistor TN thus degraded is not turned on even though the standard voltage VI is applied thereto.

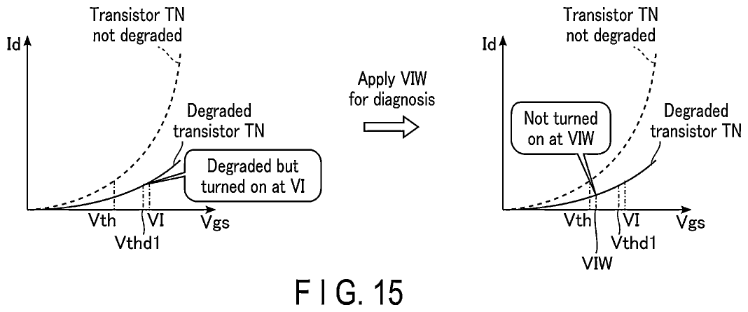

On the other hand, as shown in FIG. 15, the transistor TN has a threshold voltage Vthd1 due to degradation at a certain time. The threshold voltage Vthd1 is higher than the threshold voltage Vth but lower than the standard voltage VI. The transistor TN is thus turned on by application of the standard voltage VI. However, the transistor TN may be degraded during the next writing to have a threshold voltage (e.g., Vthd indicated in the right part of FIG. 14B) which is higher than the standard voltage VI. In this case, the transistor TN becomes incapable of being turned on even if the standard voltage VI is applied thereto at a certain time during the writing. To avoid this, as in step ST1 of FIG. 13, the degradation of the transistor TN can be specified by applying a voltage that is lower than the standard voltage VI normally applied, such as a voltage VIW, to the transistor TN. As shown in the right part of FIG. 15, the transistor TN not degraded (having characteristics indicated by the dashed line) is turned on even by the application of the voltage VIW, which is lower than the standard voltage VI, for a period of time TR, while the transistor TN having a threshold voltage Vthd1 due to degradation (having characteristics indicated by the solid line) is not turned on by the application of the voltage VIW for a period of time TR. It is thus possible to determine that the transistor TN is degraded by the application of such a voltage.

Using the foregoing phenomenon, a register 357 including the degraded transistor TN can be specified as described below. That is, each register 357 that receives certain control data DL (e.g., control data DLa) having an “H” level voltage of a standard magnitude operates normally if none of the transistors TN in the register 357 is degraded. That is, based on the control data DL, a driving voltage VD based on the “H” level is applied to the electrode 355 coupled to the register 357. If, however, any of the transistors TN is degraded, it is not turned on even upon receipt of an “H” level voltage that is lower than the “H” level voltage of the standard magnitude. Thus, the register 357 including the degraded transistor TN does not operate normally even upon receipt of the control data DL of the lower “H” level voltage. As a result, the electron beams EBm passing through the apertures 353 opposed to the electrode 355 are not blanked. Based on this, the “H” level voltage of the control data DL is made lower than the standard magnitude and thus the register 357 including the degraded transistor TN can be found.

As the “H” level voltage of the control data DL is decreased, even if, for example, a first-stage transistor TN (namely, a transistor TN1 of NAND gates ND1 and ND3) of the register 357 is normal, the output of the transistor TN is smaller than that of the “H” level voltage when the control data DL of the “H” level voltage of the standard magnitude is applied. Therefore, the voltage of the “H” level with a smaller output is also applied to the gates of the transistors TN1 at the second and subsequent stages. That is, by decreasing the “H” level voltage of the control data DL, the “H” level voltage at each node of the register 357 is smaller than the case where the “H” level voltage of the standard magnitude of the control data DL is applied. If, therefore, a certain register 357 includes one transistor TN that is not turned on upon receipt of the control data DL of the “H” level voltage of the standard magnitude, the register 357 does not operate normally. Consequently, it is possible to determine whether all of the transistors TN in a certain register 357 are normal or at least one of them is degraded by decreasing the “H” level voltage of the control data DL.

A method for specifying the degraded transistor TN based on a threshold voltage has been described with reference to FIGS. 14 and 15, but a similar phenomenon occurs with respect to the application time of the gate to source voltage Vgs. That is, the transistor TN whose characteristics are degraded cannot be turned on even by applying the standard voltage VI for the same voltage application time TI as before the degradation. Under the present circumstances, even if the time (which may be referred to as required voltage application time hereinafter) during which the gate to source voltage Vgs is applied to a transistor TN to turn on the transistor is TO, the transistor TN may degrade during the next writing and need a required voltage application time TOd (>TI). Based on this, the low-speed clock cycle is shortened as described in step ST1 of FIG. 13. The low-speed clock cycle affects the time of output of voltage from the register 357. If, therefore, the gate to source voltage Vgs, for example, the standard voltage VI, is applied to the transistor TN for a time shorter than the voltage application time TI included in the normal conditions, for example, for a period of time TOW, it is possible to specify that the transistor TN is degraded. The transistor TN not degraded is turned on even if the standard voltage VI is applied thereto only for a voltage application time TOW shorter than the required voltage application time TO. On the other hand, the transistor TN which need a required voltage application time TODI (>TOW) due to degradation is not turned on even if the standard voltage VI is applied thereto for the voltage application time TOW. It is thus possible to specify that the transistor TN is degraded by the application of the standard voltage VI for such a period of time.

Using the foregoing phenomenon, the register 357 including the degraded transistor TN does not operate normally according to the same principle as in the case where the “H” level voltage of the control data DL is decreased. Therefore, the degraded register 357 can be specified.

The n-type MOSFET TN has been described so far with reference to FIGS. 14 and 15. This description also applies to the p-type MOSFET TP. That is, the more degraded p-type transistor TP has a lower threshold voltage. The voltage application time of the p-type transistor TP1 is the same as that of the n-type transistor TN. The more degraded the transistor TP1, the longer the required voltage application time. If, therefore, if a register 357 includes at least one degraded n-type transistor TN or at least one degraded p-type transistor TP, it does not operate normally.

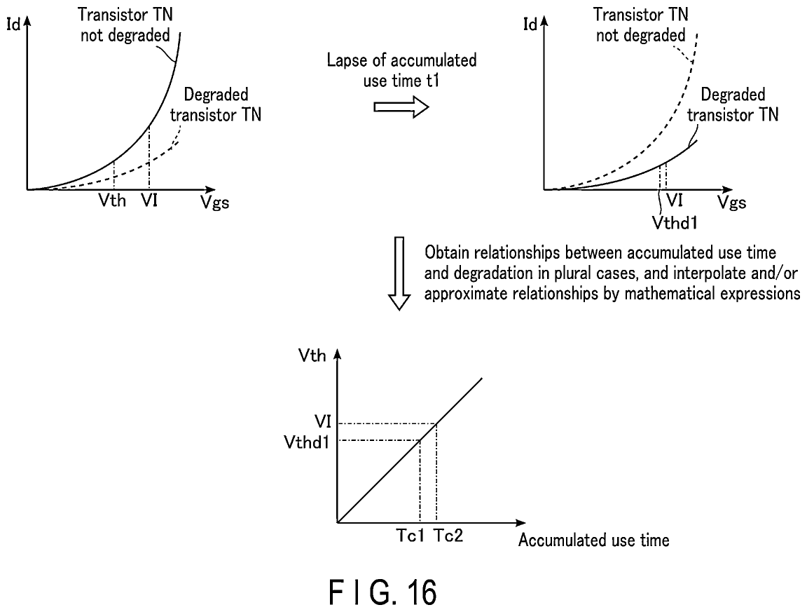

Step ST5 in FIG. 13 will be described below in more detail with reference to FIG. 16. FIG. 16 shows, as an example, the relationship between degradation and use time of the transistor TN in the register 357 of the first embodiment. The degradation of characteristics of the register 357 (especially, transistors TN and TP therein) correlates with the accumulation of time periods that have been used by the transistors TN and TP. FIG. 16 and the following descriptions relate to a transistor TNa in a register 357, which is degraded to prevent the register 357 from operating normally. FIG. 16 and the following descriptions apply to a certain degraded transistor TP.

The degradation of the transistor TN is not caused only by the use of the transistor TN itself, but depends on a period of time during which the transistor TN is exposed to the environment that degrades the transistor TN. This is because the transistor TN is degraded by the environment caused for writing, such as exposure to X-rays generated by irradiation of electron beams EBm for writing. The transistor TN thus depends at least in part upon writing time, strictly, irradiation time of electron beams EBm. This relationship is used to estimate failure time in step ST4 of FIG. 13.

Assume as an example that the threshold voltage of the transistor TN increases due to degradation after a lapse of accumulated time t1 during which writing is performed. In this example, a difference between a threshold voltage Vth before degradation and a threshold voltage Vthd1 after degradation correlates with the time t1. The relationship between the accumulated time and the difference between threshold voltages before and after degradation is obtained in advance by experiment and/or simulation for a variety of cases. For example, the average of relationships among a plurality of transistors TN or the relationship for one of the transistors TN is used as a representative. A plurality of discrete relationships thus obtained are interpolated or approximated by mathematical expressions. As a result, as shown in the lower part of FIG. 16, the relationship between the accumulated use time of the transistors TN and the current threshold voltage is obtained. FIG. 16 shows, as an example, a linear relationship. For example, this relationship is stored in the storage device 213 at the start of use of the writing apparatus 1. The BAA diagnostic unit 225 uses the relationship to calculate estimated failure time.

Assume that for example, the transistor TNa is used for a period of accumulated use time Tc1 and has a threshold voltage Vthd1 (<standard voltage VI) during the period. Also, assume that accumulated use time required until the threshold voltage of the transistor TNa becomes equal to the standard voltage VI is Tc2. In this case, the time required until the threshold voltage of the transistor TNa reaches the standard voltage VI is Tc2−Tc1. The time thus calculated is the estimated failure time of the transistor TNa, that is, the estimated failure time of the register 357 including the transistor TNa.

The same applies to the required voltage application time. If the required voltage application time increases due to degradation after a lapse of the accumulated time t1, a difference between required voltage application time TO before degradation and required voltage application time TOd after degradation correlates with the accumulated time t1. The relationship between the accumulated time and the difference between the required voltage application times before degradation and after degradation is obtained in advance by experiment and/or simulation in a variety of cases. A plurality of discrete relationships thus obtained are interpolated or approximated by mathematical expressions. Thus, the relationship between the accumulated time and the difference between the required voltage application time before and after degradation is used to estimate the time required until the transistor TN1 estimated to have required voltage application time TOd1 (<TI) exceeds the required voltage application time TI. The estimated time is the estimated failure time.

As described above, the estimated failure time may be based on both the threshold voltage Vth and the required voltage application time TO. In addition, another characteristic value may be used as a degradation indicator of the transistors TN and/or TP.

In the foregoing descriptions, as an example, it is determined whether the register 357 (shift register 3571) fails (or, operates normally) according to whether a blanking state in which electron beams EBm are blanked by applying a driving voltage DV to the electrode 355 coupled to the register 357 in accordance with the control data DL for the register 357 coincides with the blanking state of electron beams EBm formed by applying a driving voltage DV to the electrode 355 coupled to the register in accordance with the control data DL. The embodiment is not limited to this example. The failure determination may also be based on whether or not the control data DL supplied to a first-stage (or, initial-stage) register 357 of the shift register 3571 coincides with this control data DL after having been transferred through the shift register 3571 and output from one of the registers 357.

### 1.3. Advantages

According to the first embodiment, the BAA diagnostic unit 225 applies a voltage and/or a low-speed clock signal SCLK to the register 357 under conditions that are worse than those used during normal writing, calculates conditions under which the register 357 which does not operate normally become to operate normally, and estimates, based on the calculated conditions, the time required until the register 357 fails. Based on the estimated failure time, the BAA diagnostic unit 225 can specify a register 357 that may fail during the next writing. This can prevent the register 357 from failing unexpectedly before and during writing.

### 1.4. Modification

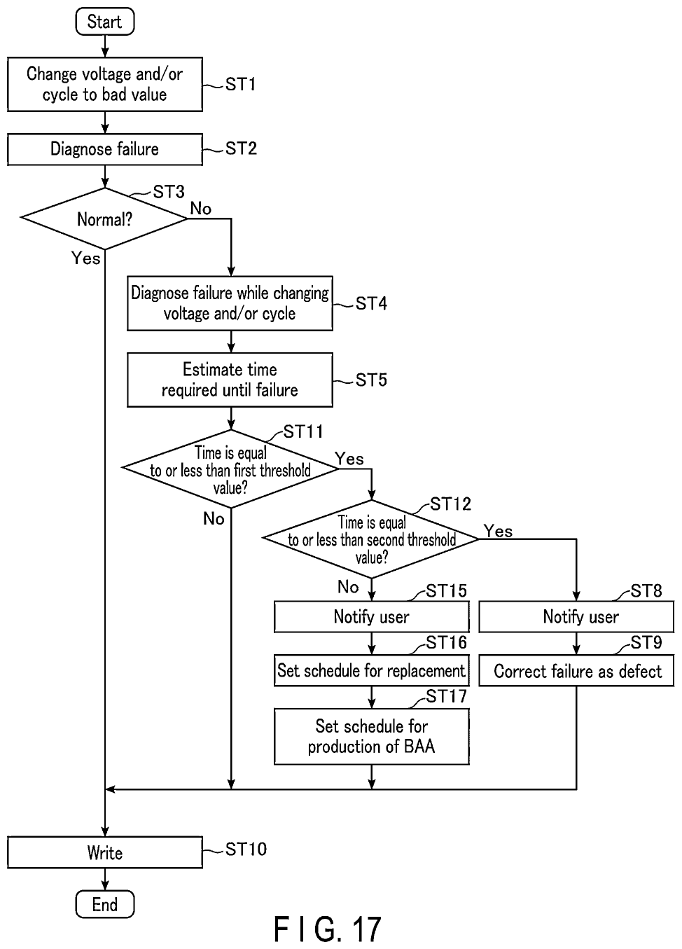

The determination performed with the estimated failure time used may also be used for the scheduling of the replacement and production of the blanking aperture array mechanism. FIG. 17 shows a process of such scheduling and also shows a writing and inspecting method according to a modification of the first embodiment. The elements that are only different from those of the first embodiment described with reference to FIG. 13 will be described with reference to FIG. 17.

As shown in FIG. 17, step ST5 continues to step ST11. In step ST11, the BAA diagnostic unit 225 determines whether the estimated failure times of each of the target registers 357t is equal to or less than a first threshold value Th1. The first threshold value Th1 is larger than the threshold value with which the estimated failure time is compared in step ST6 shown in FIG. 13 of the first embodiment. The first threshold value Th1 can be set, for example, to a time period which is determined based on a writing plan and at least during which the user desires the blanking aperture array mechanism 350 to be normal. Alternatively, the first threshold value Th1 may be set, for example, to a period of time that is longer than a period of time from the current time until manufacturing of a blanking aperture array mechanism 350 is completed and substituted for a failed one. The first threshold value Th1 may be input by the user in advance, for example, particularly before the start of the flow of FIG. 17.

If the estimated failure time of each of the target registers 357t is not equal to or less than the first threshold value Th1 (No in step ST11), it is considered that no failure occurs in the components of the blanking aperture array mechanism 350 for a while. Therefore, the process proceeds to step ST10.

If the estimated failure time of each of the target registers 357t is equal to or less than the first threshold value Th1 (Yes in step ST11), the process proceeds to step ST12. In step ST12, the BAA diagnostic unit 225 determines whether the estimated failure time of each of the target registers 357t is equal to or less than a second threshold value Th2. The second threshold value Th2 is smaller than the first threshold value Th1 and is, for example, the same as a threshold value with which the estimated failure time is compared in step ST6 of the first embodiment.

If the estimated failure time of any one of the target registers 357t is not equal to or less than the second threshold value Th2 (or, exceeds the second threshold value Th2) (No in step ST12), no failure occurs in the components of the blanking aperture array mechanism 350 during writing performed the number of times based on the second threshold value Th2, but a failure may occur in the near future. In view of this, in step ST15, the BAA diagnostic unit 225 notifies the user by using, for example, the output device 215 that a failure may occur in the near future.

If the estimated failure time of each of the target registers 357t is equal to or less than the second threshold value Th2 (Yes in step ST12), the process proceeds to step ST8. Step ST8 continues to step ST9, and step ST9 continues to step ST10.

In step ST16, the BAA diagnostic unit 225 schedules the time (or, date and time) of replacement of the blanking aperture array mechanism 350 based on the determination that a failure may occur in the near future. The replacement time is based on the estimated failure time. For example, the replacement time is set on the basis of the number of times the user is supposed to perform writing (for example, the average number of times) before the total time for which the writing is to be performed exceeds the estimated failure time. The manufacturer of the writing apparatus 1 is notified of the replacement time. For example, data indicating the replacement time is transmitted to the manufacturer of the writing apparatus 1 via the communication device 217.

In step ST17, the manufacturer of the writing apparatus 1 knows the replacement time from the data indicating the replacement time, and sets a production schedule of a new blanking aperture array mechanism 350 based on the replacement time. Step ST17 continues to step ST10.

Steps ST15, ST16 and ST17 may be executed in a different order from that shown in FIG. 17 or may be executed in parallel.

The present invention is not limited to the above-described embodiments, and can be modified in various manners in practice when implementing the invention without departing from the gist of the invention. Moreover, the embodiments can be suitably combined; in that case, the combined advantages are obtained. Furthermore, the above-described embodiments include various inventions, and a variety of inventions can be derived by suitably combining structural elements disclosed in connection with the embodiments. For example, if the object of the invention is achieved and the advantages of the invention are attained even after some of the structural elements disclosed in connection with the embodiments are deleted, the structure made up of the resultant structural elements can be extracted as an invention.

What is claimed is:

1. A blanking aperture array system for use in a multi-charged particle beam irradiation apparatus, comprising:
a blanking aperture array substrate including:
a shift register including a plurality of flip-flops coupled in series and configured to transfer control data for beam irradiation; and
first electrodes respectively coupled to the flip-flops and formed on a substrate and second electrodes coupled to ground, one of the first electrodes and one of the second electrodes sandwiching one of a plurality of apertures through which a beam is transmitted; and
a controller which:
supplies, during beam irradiation, the shift register with the control data which causes the flip-flops to hold a “1” value and has a first voltage that is used during beam irradiation; and
supplies, during a period except for the beam irradiation, the shift register with the control data which causes the flip-flops to hold a “1” value and has a second voltage that is lower than the first voltage to determine whether the flip-flops are operating normally by determining whether the control data supplied to the shift register coincides with control data output from one of the flip-flops in the shift register as a result of the control data transferred through the shift register or by determining whether a state to be obtained by blanking by one of the first electrodes coupled to a first flip-flop in the shift register in accordance with the control data supplied to the shift register coincides with a state obtained by blanking by the one of the first electrodes coupled to the first flip-flop in accordance with the control data supplied to the shift register.

2. The blanking aperture array system of claim 1, wherein:
the second voltage is a lower limit value at which a transistor included in one of the flip-flops is turned on; and
when a first flip-flop of the flip-flops does not operate normally with the shift register supplied with the control data which causes the flip-flops to hold a “1” value and has the second voltage, the controller:
repeatedly supplies the shift register with the control data which causes the flip-flops to hold a “1” value with different voltages between the first voltage and the second voltage;
determines, among the different voltages, a third voltage which causes the first flip-flop to operate normally and which is closest to the second voltage;
estimates a first time until the first flip-flop stops operating normally even with the shift register supplied with the control data which causes the flip-flops to hold a “1” value by using a relationship between accumulated use time of the first flip-flop and a threshold voltage; and
compares the first time with reference time.

3. The blanking aperture array system of claim 2, wherein when the first time exceeds the reference time, the shift register is supplied with the control data which causes the flip-flops to hold a “1” value and has a voltage that is higher than the first voltage.

4. A blanking aperture array system for use in a multi-charged particle beam irradiation apparatus, comprising:
a blanking aperture array substrate including:
a shift register including a plurality of flip-flops coupled in series and configured to receive a clock and transfer control data for beam irradiation at timing based on the clock; and
a first electrode coupled to each of the flip-flops and formed on a substrate and a second electrode coupled to ground, the first electrode and the second electrode sandwiching one of a plurality of apertures; and
a controller which:
supplies the shift register with the clock having a first cycle during beam irradiation; and
supplies, during a period except for the beam irradiation, the shift register with the clock having a second cycle that is shorter than the first cycle to determine whether the flip-flops are operating normally by determining whether the control data supplied to the shift register coincides with control data output from one of the flip-flops in the shift register as a result of the control data transferred through the shift resistor or by determining whether a state to be obtained by blanking by one of the first electrodes coupled to a first flip-flop in the shift register in accordance with the control data supplied to the shift register coincides with a state obtained by blanking by the one of the first electrodes coupled to the first-flop in accordance with the control data supplied to the shift register.

5. The blanking aperture array system of claim 4, wherein:
the second cycle is a lower limit value at which the shift register operates normally; and
when a first flip-flop of the flip-flops does not operate normally with the shift register supplied with the clock having the second cycle, the controller:
repeatedly supplies the shift register with the clock having different cycles between the first cycle and the second cycle;
determines, among the different cycles, a third cycle which causes the first flip-flop to operate normally and which is closest to the second cycle;
estimates a first time until the first flip-flop stops operating normally even with the shift register supplied with the clock having the first cycle by using a relationship between accumulated use time of the first flip-flop and the cycle of the clock; and
compares the first time with the reference time.

6. The blanking aperture array system of claim 5, wherein when the first time exceeds the reference time, the shift register is supplied with the clock having a cycle longer than the first cycle.

7. A charged particle beam writing apparatus comprising:
a movable stage;
a beam source located above the stage; and
the blanking aperture array system of claim 1, located between the beam source and the stage.

8. A charged particle beam writing apparatus comprising:
a movable stage;
a beam source located above the stage; and
the blanking aperture array system of claim 2, located between the beam source and the stage.

9. A charged particle beam writing apparatus comprising:
a movable stage;
a beam source located above the stage; and
the blanking aperture array system of claim 3, located between the beam source and the stage.

10. A charged particle beam writing apparatus comprising:
a movable stage;
a beam source located above the stage; and
the blanking aperture array system of claim 4, located between the beam source and the stage.

11. A charged particle beam writing apparatus comprising:
a movable stage;
a beam source located above the stage; and
the blanking aperture array system of claim 5, located between the beam source and the stage.

12. A charged particle beam writing apparatus comprising:
a movable stage;
a beam source located above the stage; and
the blanking aperture array system of claim 6, located between the beam source and the stage.

13. A method of inspecting a blanking aperture array system for use in a multi-charged particle beam irradiation apparatus, the blanking aperture array system including:
a shift register including a plurality of flip-flops coupled in series and configured to transfer control data for beam irradiation; and
first electrodes respectively coupled to the flip-flops and formed on a substrate and second electrodes coupled to ground, one of the first electrodes and one of the second electrodes sandwiching one of a plurality of apertures,
the method comprising:
supplying the shift register with control data which causes the flip-flops to hold a “1” value and has a first voltage during beam irradiation; and
supplying, during a period except for the beam irradiation, the shift register with the control data which causes the flip-flops to hold a “1” value and has a second voltage that is lower than the first voltage to determine whether the flip-flops are operating normally by determining whether the control data supplied to the shift register coincides with the control data received from one of the flip-flops in the shift register or by determining whether a state of blanking by one of the first electrodes coupled to one of the flip-flops in the shift register coincides with a state of blanking indicated by the control data supplied to the shift register.

14. A method of inspecting a blanking aperture array system for use in a multi-charged particle beam irradiation apparatus, the blanking aperture array system including:
a shift register including a plurality of flip-flops coupled in series and configured to receive a clock and transfer control data for beam irradiation at timing based on the clock; and
a first electrode coupled to each of the flip-flops and formed on a substrate and a second electrode coupled to ground, the first electrode and the second electrode sandwiching one of a plurality of apertures,
the method comprising:
supplying the shift register with the clock having a first cycle during beam irradiation; and
supplying, during a period except for the beam irradiation, the shift register with the clock having a second cycle that is shorter than the first cycle to determine whether the flip-flops are operating normally by determining whether the control data supplied to the shift register coincides with the control data received from one of the flip-flops in the shift register or by determining whether a state of blanking by one of the first electrodes coupled to one of the flip-flops in the shift register coincides with a state of blanking indicated by the control data supplied to the shift register.

15. The method of claim 13, wherein:
the second voltage is a lower limit value at which a transistor included in one of the flip-flops is turned on; and
when a first flip-flop of the flip-flops does not operate normally with the shift register supplied with the control data which causes the flip-flops to hold a “1” value and has the second voltage, the method further comprises:
repeatedly supplying the shift register with the control data which causes the flip-flops to hold a “1” value with different voltages between the first voltage and the second voltage;
determining, among the different voltages, a third voltage which causes the first flip-flop to operate normally and which is closest to the second voltage;
estimating a first time until the first flip-flop stops operating normally with the shift register supplied with the control data which causes the flip-flops to hold a “1” value by using a relationship between accumulated use time of the first flip-flop and a threshold voltage;
comparing the first time with a first threshold value;
supplying the shift register with the control data which causes the flip-flops to hold a “1” value and has the first voltage during the beam irradiation when the first time is not equal to or less than the first threshold value;
comparing the first time with a second threshold value that is smaller than the first threshold value;
supplying the shift register with the control data which causes the flip-flops to hold a “1” value and has a fourth voltage that is higher than the first voltage during the beam irradiation when the first time is equal to or less than the second threshold value;
setting a schedule for replacement of the blanking aperture array system based on the first time when the first time is equal to or less than the second threshold value; and
setting a schedule for production of a new blanking aperture array system based on the schedule for replacement.

16. The method of claim 14, wherein:
the second cycle is a lower limit value at which the shift register operates normally; and
when a first flip-flop of the flip-flops does not operate normally with the shift register supplied with the clock having the second cycle, the method further comprising:
repeatedly supplying the shift register with clock having different cycles between the first cycle and the second cycle;
determining, among the different cycles, a third cycle which causes the first flip-flop to operate normally and which is closest to the second cycle;
estimating a first time until the first flip-flop stops operating normally even with the shift register supplied with the clock having the first cycle by using a relationship between accumulated use time of the first flip-flop and the cycle of the clock;
making a first comparison to compare the first time with a first threshold value, supplying the shift register with the clock having the first cycle during the beam irradiation when the first time is not equal to or less than the first threshold value as a result of the first comparison, and making a second comparison to compare the first time with a second threshold value that is less than the first threshold value when the first time is equal to or less than the first threshold value as a result of the first comparison;
setting a schedule for replacement of the blanking aperture array system based on the first time when the first time is not equal to or less than the second threshold value as a result of the second comparison, setting a schedule for production of a new blanking aperture array system based on the schedule for replacement, and supplying the shift register with the clock having a fourth cycle that is longer than the first cycle during the beam irradiation when the first time is equal to or less than the second threshold value.
